(19) United States
(12) Patent Application Publication
(10) Pub. No.: US 2013/0210317 A1
(43) Pub. Date: Aug. 15, 2013

(54) Protective Case for Portable Electronic Device

(71) Applicant: MATTEL, INC., (US)

(72) Inventors: Beth Ann Hageman, Orchard Park, NY (US); Daniel J. Damon, South Wales, NY (US); Christine A. Drosendahl, East Aurora, NY (US); Anthony Favorito, Buffalo, NY (US); Jared P. Pardi, Cheektowaga, NY (US); John Thaddeus Smokowski, West Seneca, NY (US); Gary E. Weber, Buffalo, NY (US)

(73) Assignee: MATTEL, INC., El Segundo, CA (US)

(21) Appl. No.: 13/755,164

(22) Filed: Jan. 31, 2013

Related U.S. Application Data
(60) Provisional application No. 61/596,759, filed on Feb. 9, 2012.

(51) Int. Cl. A63H 33/00; H05K 5/03

(52) U.S. Cl. CPC A63H 33/00; H05K 5/03
USPC 446/396; 312/223.1

(57) ABSTRACT

A protective case for a portable electronic device includes a cover having an aperture and sidewalls defining a cavity configured for releasably receiving a portable electronic device. A back plate is removably disposed within the cavity of the cover. The protective case contains at least two supports movably coupled to the protective case, enabling the protective case and electronic device to be positioned in various orientations. The supports pivot independent of each other into deployed or stowed positions.

### CROSS-REFERENCE TO RELATED APPLICATION

This application claims priority to and the benefit of U.S. Provisional Patent Application No. 61/596,759, filed Feb. 9, 2012, Attorney Docket No. 0621.1911P, entitled “Protective Case for Portable Electronic Device,” the entire disclosure of which is incorporated herein by reference in its entirety.

### FIELD OF THE INVENTION

The present invention relates to a protective case for a portable electronic device, and in particular, a child friendly and “kid-tough” protective case for an electronic device.

### BACKGROUND OF THE INVENTION

Various protective covers, cases, and sleeves for portable electronic devices, such as cellular phones, smart devices, media players, and portable computers, are known. Some designs provide additional protection to the device from damage, but do not permit use of the device when disposed in the protective cover. Other designs permit use of the device when disposed in the cover, but do not sufficiently protect the device from damage, misuse, or unauthorized use when handled by young children or infants. Furthermore, some designs provide additional support members to position the electronic devices in orientations optimal for viewing the screen of the electronic device.

Therefore, there is a need for a protective case for a portable electronic device that is appropriate for use by infants and young children. In addition, there is a need for a protective case for a portable electronic device that provides auxiliary features for entertaining an infant or child. Furthermore, there is a need for a protective case for a portable electronic device that provides multiple supports for positioning the protective case and electronic device in a variety of orientations for use by infants and young children.

### SUMMARY OF THE INVENTION

The present invention is directed to a child-friendly and kid-tough case for receiving a portable electronic device, including, but not limited to an iPad® or another tablet-type device. In some embodiments, in addition to holding the hand-held electronic device, the protective case includes pivotable or repositionable supports that enable the protective case to be stably propped-up on a support surface or rock side-to-side on a support surface. Moreover, in some embodiments, the protective case includes child or infant appropriate mechanical activities, such as clacker beads or rings, around its perimeter.

The front of the protective case includes a semi-rigid thin film protective cover for the screen of the electronic device. This film is thin enough so that the touch sensitive features of the electronic device may still be activated through the film. The front of the case also includes a more rigid plate, band, or thickened portion that covers a portion of the front of the electronic device or a portion of the display screen of the electronic device (e.g., the “Home” button on the electronic device). The rigid plate does not permit activation by the user of any actuators on the covered portion of the front of the electronic device (e.g., the “Home” button). The hand-held electronic device may be placed in a first position within the protective case so that the portion of the front of the electronic device or a portion of the display screen of the electronic device is covered by the rigid band and not actuable, or the device may be rotated 180° so that the originally covered portion of the front of the electronic device or a portion of the display screen of the electronic device is visible and actuable through the thin film protective cover.

In one embodiment, a protective case for a portable electronic device includes a cover having a top, bottom, and sides containing sidewalls that define a cavity configured for receiving the portable electronic device. A back plate has a top, a bottom, and sides that define an inner surface having resilient members for retaining and positioning the portable electronic device within the cover. The cover contains an outer surface that includes a transparent planar portion. The portable electronic device is disposable within the cavity defined by the sidewalls of the cover and between the back plate and the transparent planar portion of the cover so that at least a portion of a display of the portable electronic device is visible through the transparent planar portion.

In one embodiment, a protective case for a portable electronic device includes a housing configured to surround a portion of an electronic device. The housing contains an aperture for viewing and interacting with the electronic device. The protective case further includes a first support movably coupled to the housing and a second support movably coupled to the housing. The first and second supports have a curved surface engageable with a support surface. Each of the supports is pivotable between a retracted position relative to the housing and a deployed position that allows the housing to rock from side-to-side.

In one embodiment, the housing includes a front cover and a removable back plate for housing an electronic device, where first and second supports are movably coupled to the removable back plate. The first and second supports are pivotable independent of each other relative to the housing. The front cover contains an aperture for viewing and interacting with the electronic device. The aperture further includes a protective guard film for protecting the screen of the electronic device from dirt and debris. Furthermore, the protective case contains an arch member with a first end and a second end opposite the first end, the arch being coupled to the cover at the first end and the second end, and an activity bead slidably disposed on the arch.

In another embodiment, the protective case for an electronic portable device includes a cover configured to surround a portion of an electronic device and having an aperture for viewing and interacting with the electronic device. The protective case also includes a removable back plate that is coupleable to the cover. Furthermore, the protective case contains a first rounded support and a second rounded support, each being coupled to the back plate and pivotable between a stowed position in which the rounded support is proximate to the back plate, and a deployed position that allows the cover to rock from side-to-side on a supporting surface.

In one embodiment, the back plate of the protective case includes at least one lock for locking the back plate onto the cover. Additionally, the back plate includes at least one tab for facilitating removal of the back plate from the cover. The tab is graspable by a user's fingers or fingernail. The cover of the protective case includes at least one guard disposed on the cover, the guard being configured to protect a screen of the electronic device while making the screen of the electronic device viewable and interactable. The guard serves to prevent debris and dirt from coming in contact with the electronic device while within the protective case. The guard further includes at least one plate being configured to prevent activation by the user of any actuators on the portion of the front of the device (e.g., the “Home” button) covered by the plate.

In another embodiment, the protective case for an electronic portable device includes a cover configured to house an portable electronic device. The cover includes a front with an aperture, and a back with a cavity. The protective case also includes a back plate dimensioned to removably fit within the cavity on the back of the cover. At least two rounded supports are pivotally mounted to the back plate and configured for two positions, a deployed position where the rounded support is positioned perpendicular to the back plate, and a stowed position where the rounded support lays flat proximate to the back plate. Moreover, the protective case contains a protective sheet sealed to the aperture on the front of the cover and configured to prevent debris and liquids from contacting a portable electronic device housed within the protective case.

In one embodiment, the protective sheet of the protective case includes at least one plate being configured to prevent activation by the user of any actuators on the portion of the front of the portable electronic device (e.g., the “Home” button) covered by the plate. Furthermore, the cover of the protective case includes at least one retention member within the cavity of the cover. The retention member is configured to position the portable electronic device to be viewed through the aperture. The back plate of the protective case includes at least one resilient member to retain the portable electronic device in position between the cover and the back plate.

### BRIEF DESCRIPTION OF THE DRAWINGS

FIG. 1 illustrates schematic block diagram of an embodiment of a product according to the present invention;

FIG. 2 illustrates a front perspective view of a protective case for a portable electronic device according to an embodiment of the present invention;

FIG. 3 illustrates a rear perspective view of the case of FIG. 2;

FIG. 3A illustrates an assembly view of the cover and back plate in accordance with the present invention of FIG. 2;

FIG. 4 illustrates a rear perspective view of the cover of the case of FIG. 2 with the back plate removed;

FIG. 5 illustrates a perspective view of a corner retention member in the cavity of the cover of FIG. 4;

FIG. 6 illustrates a rear perspective view of the top of the cover of FIG. 4;

FIG. 7 illustrates a rear perspective view of the bottom of the cover of FIG. 4;

FIG. 8 illustrates a perspective view of the interior portion of the back plate of the case of FIG. 1;

FIG. 9 illustrates a perspective view of the outside portion of the back plate of FIG. 8 showing the first and second support members in a first orientation;

FIG. 10 illustrates a perspective view of the assembly of the protective case of FIG. 2;

FIG. 11 illustrates a perspective view of the outside portion of the back plate of FIG. 8 showing the first support member pivoted into a second orientation;

FIG. 12 illustrates a side view of the back plate of FIG. 11 showing the first support member pivoted a second orientation;

FIG. 13 illustrates a side view of the back plate of FIG. 11 showing the orientation of the back plate on a support surface with the first support member pivoted into a second orientation;

FIG. 14 illustrates a perspective view of the protective case of FIG. 2 in use with the first support pivoted into a second orientation;

FIG. 15 illustrates a side view of the back plate of FIG. 8 showing the first and second support members pivoted into the a second orientation;

FIG. 16 illustrates a top view of the back plate of FIG. 15 showing the first and second support members pivoted into a second orientation;

FIG. 17 illustrates a top view of the back plate of FIG. 15 showing the orientation of the back plate on a support surface with the first and second support members pivoted into a second orientation;

FIG. 18 illustrates a perspective view of the protective case of FIG. 2 in use with the first and second supports pivoted into a second orientation;

FIG. 19 illustrates a perspective view of the insertion and alignment of the portable electronic device into a first orientation within the cover of FIG. 4;

FIG. 20 illustrates a perspective view of the insertion and alignment of the portable electronic device into a second orientation within the cover of FIG. 4;

FIG. 21 illustrates a front perspective view of the protective case of FIG. 2 containing the portable electronic device; and

FIG. 22 illustrates a front perspective view of the protective case of FIG. 2 showing the home button of the portable electronic device aligned with the plate of protective case.

Like reference numerals have been used to identify like elements throughout this disclosure.

### DETAILED DESCRIPTION OF THE INVENTION

This application incorporates herein by reference, in its entirety, the disclosure of U.S. Non-Provisional application Ser. No. 13/351,811, entitled “Protective Case for Portable Electronic Device”, filed Jan. 17, 2012.

It is to be understood that terms such as “left,” “right,” “top,” “bottom,” “front,” “rear,” “side,” “height,” “length,” “width,” “upper,” “lower,” “interior,” “exterior,” “inner,” “outer” and the like as may be used herein, merely describe points or portions of reference and do not limit the present invention to any particular orientation or configuration. Further, terms such as “first,” “second,” “third,” etc., merely identify one of a number of portions, components and/or points of reference as may be described herein, and do not limit the present invention to any particular configuration or orientation.

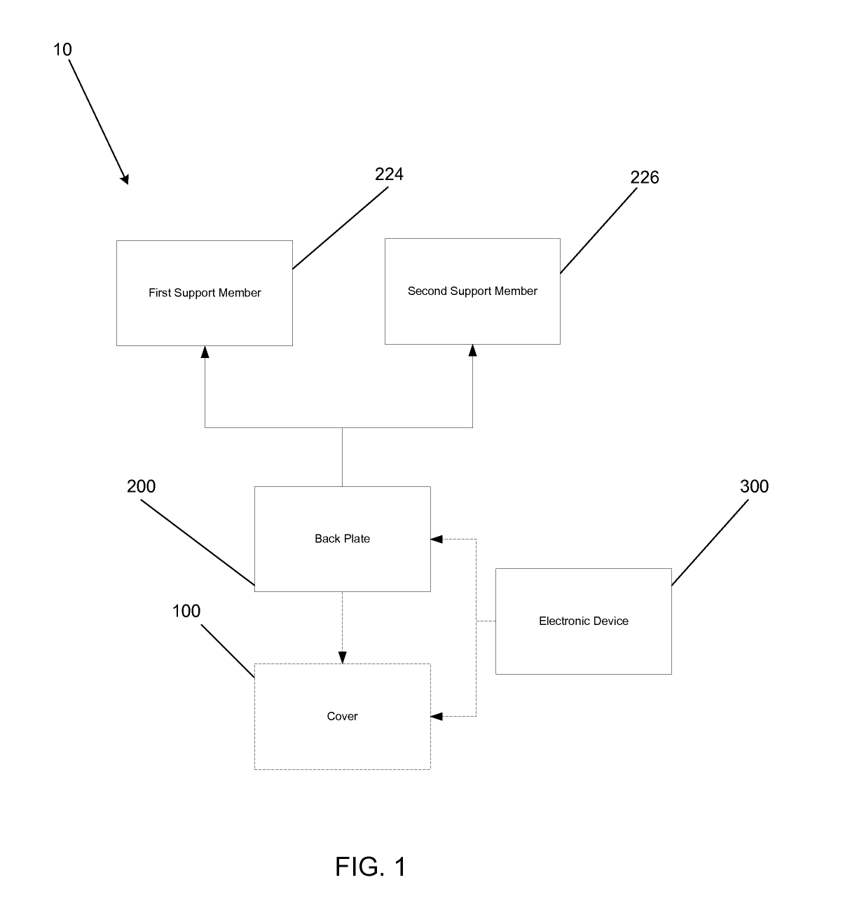

FIG. 1 illustrates a schematic diagram of one embodiment of a protective case 10 for a portable electronic device 300. The protective case 10 contains at least a housing or back plate 200 that houses the electronic device 300. Attached to the back plate 200 are a first support member 224 and a second support member 226. The support members 224, 226 may be movably coupled to the back plate 200. Moreover, the support members 224, 226 may be movable independent of each other.

Furthermore, as illustrated in FIG. 1, in one embodiment, the protective case 10 contains a back plate 200 and a cover 100. The electronic device 300 may be housed in the cover 100, the back plate 200, or a combination of the cover 100 and back plate 200. Moreover, first support member 224 and second support member 226 may be movably coupled to the back plate 200. The support members 224, 226 may be movable independent of each other.

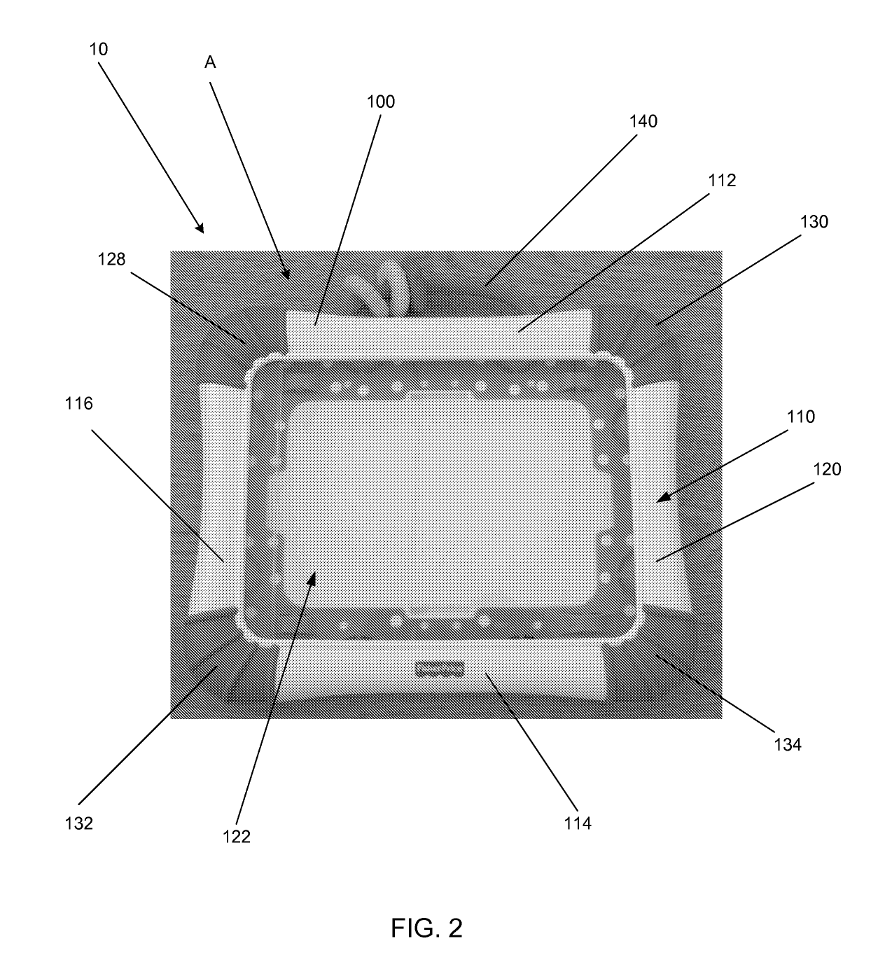

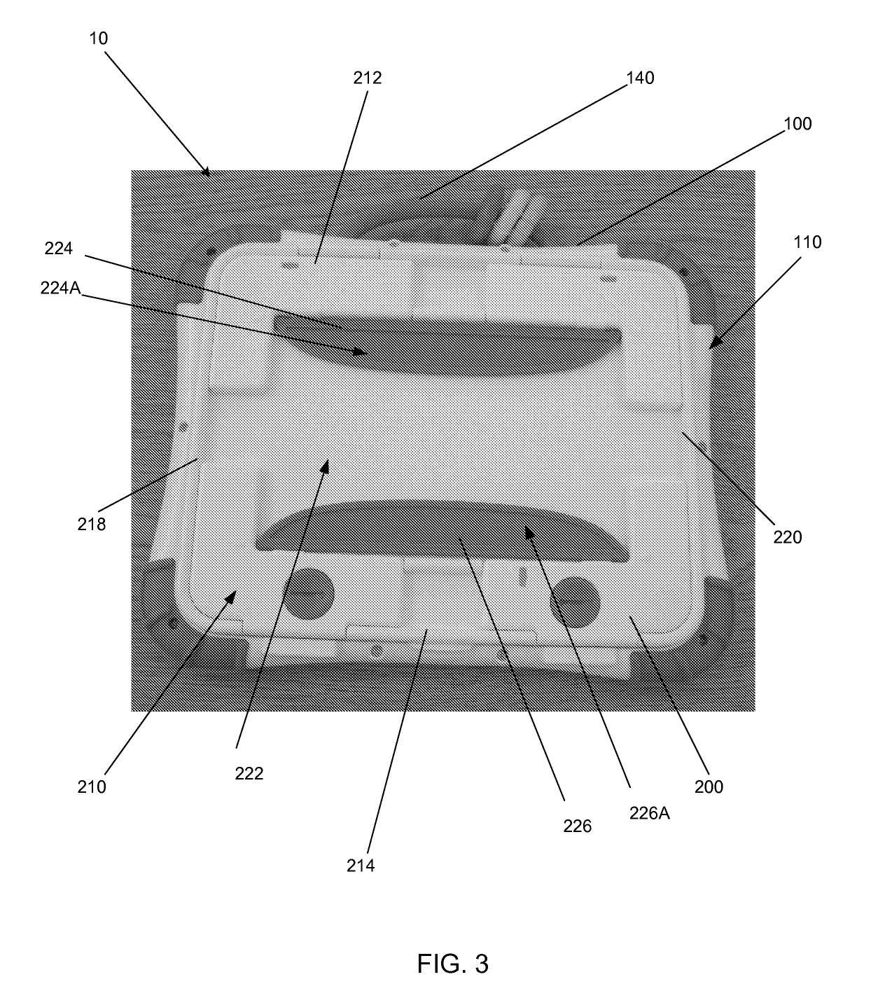

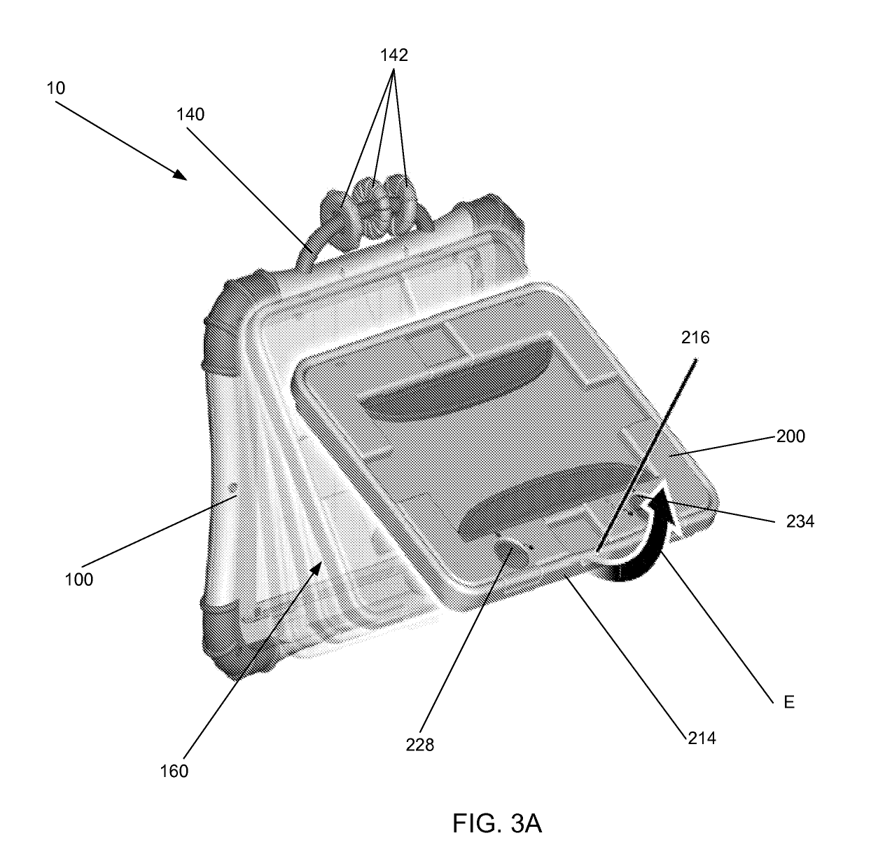

Referring to FIGS. 2 and 3, the case 10 is illustrated in the first orientation A, where the first support 224 and the second support 226 are in the stowed position 224A and 226A where the supports 224, 226 are located flat proximate to the back plate 200. In the first orientation A, the case 10 lays flat against the support surface. The cover 100 includes an outer surface 110 with a top portion 112, a bottom portion 114, a left portion 116, and a right portion 120. The cover 100 may be formed from a relatively rigid material, such as a polymer material. For example, the cover 100 may be formed from acrylonitrile butadiene styrene (ABS). Located at the intersection of each of the portions 112, 114, 116, 120 are corner bumpers 128, 130, 132, 134. First corner bumper 128 covers the intersection of top portion 112 and left portion 116. Second corner bumper 130 covers the intersection of top portion 112 and right portion 120. Third corner bumper 132 covers the intersection of bottom portion 114 and left portion 116. Fourth corner bumper 134 covers the intersection of bottom portion 114 and right portion 120. In one embodiment, each of the corner bumpers 128, 130, 132, 134 include an overmold formed from a thermoplastic material. For example a material such as polyvinyl chloride (PVC), which includes the ridged surface, may be used for enhanced grippability.

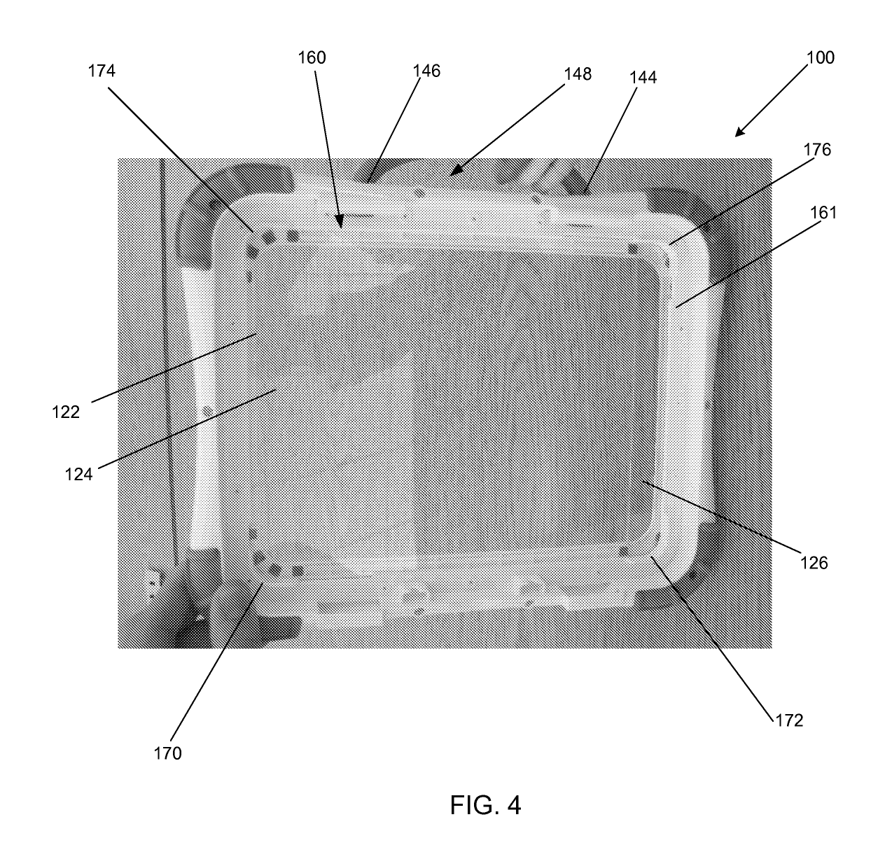

An arch handle 140 may be coupled to and extending outwardly from the top portion 112. The handle 140 may have a first end 144 attached to the top portion 112 and a second end 146 attached to the top portion 140 (see FIG. 4). The handle 140 has an arcuate and generally convex configuration. The handle 140 may include a plurality of knurls, ridges, or a textured surface for ease of gripping. The handle 140 may also be formed from a thermoplastic material, such as PVC. An opening 148 is defined by the handle 140 and the top portion 112 of the outer surface 110 of the cover 100. One or more entertainment elements may be coupled to the handle 140. In one embodiment, clacker beads or rings 142 are coupled to the handle 140 (see FIG. 3A). The beads or rings 142 (or other entertainment elements) are movable along the handle 140 and between opposing ends 144 and 146. The protective case 10 may also include additional or alternative entertainment elements.

With continued reference to FIG. 2, the outside surface 110 of cover 100 may include an aperture 122 through which a portion of the screen 302 of electronic device 300 is visible. In one embodiment, the cover 100 may contain a protective sheet 124 that expands over the aperture 122. This protective sheet 124 may be a thin transparent planar member through which actuation of the touch screen 302 of the electronic device 300 is capable by a user 400.

With continued reference to FIG. 3, the back plate 200 includes an outer surface 210 with a top portion 212, a bottom portion 214, a left portion 218, and a right portion 220. Defined within the top portion 212, the bottom portion 214, the left portion 218, and the right portion 220 is recess 222. Recess 222 may contain a first support member 224 and a second support member 226. First support member 224 and second support member 226 may be pivotally connected to the back plate 200 within recess 222. First support member 224 and second support member 226 may pivot independent of each other with respect to the back plate 200. The back plate 200 may be formed from a relatively rigid material, such as a polymer material. For example, the back plate 200 may be formed from ABS. As illustrated in FIG. 3, back plate nests within the cover 100.

Referring to FIG. 3A, illustrated is the interaction of the cover 100 and back plate 200 with each other for one embodiment of the case 10. The rear of cover 100 defines an interior cavity 160. As shown in FIG. 3A, back plate 200 is configured to rest within cavity 160. Movement of back plate 200 from within cavity 160 is facilitated by pulling on tab 216 located on the bottom 214 of back plate 200. Back plate 200 is rotated up and out of cavity 160 disconnecting from cover 100, as indicated by E.

Referring to FIG. 4, cover 100 may contain an interior cavity 160, with an inner cavity base 161 that may have a first corner retention member 170, a second corner retention member 172, a third corner retention member 174, and a fourth corner retention member 176. The corner retention members 170, 172, 174, 176 enable positioning of an electronic device 300 within the cavity 160 for the screen 302 of the electronic device 300 to be viewed by a user 400 through the aperture 122. The corner retention members 170, 172, 174, 176 are configured to be sized to extend from the inner cavity base 161 to position the electronic device 300 within the cavity 160 while not preventing the back plate 200 from being received by the cavity 160. Each of the corner members 170, 172, 174, 176 are positioned within cavity 160 to be proximate to the corners of the aperture 122 to ensure placement of the electronic device 300 within the cavity 160 of cover 100 enables users 400 to view the screen 302 of the electronic device 300 through the aperture 122.

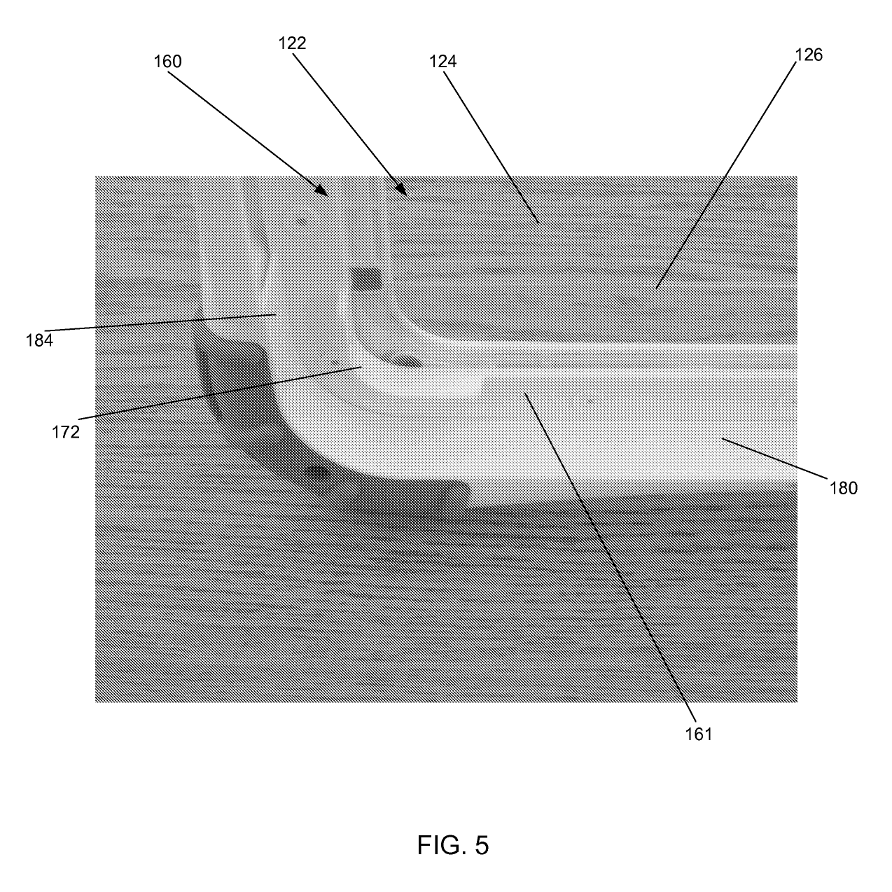

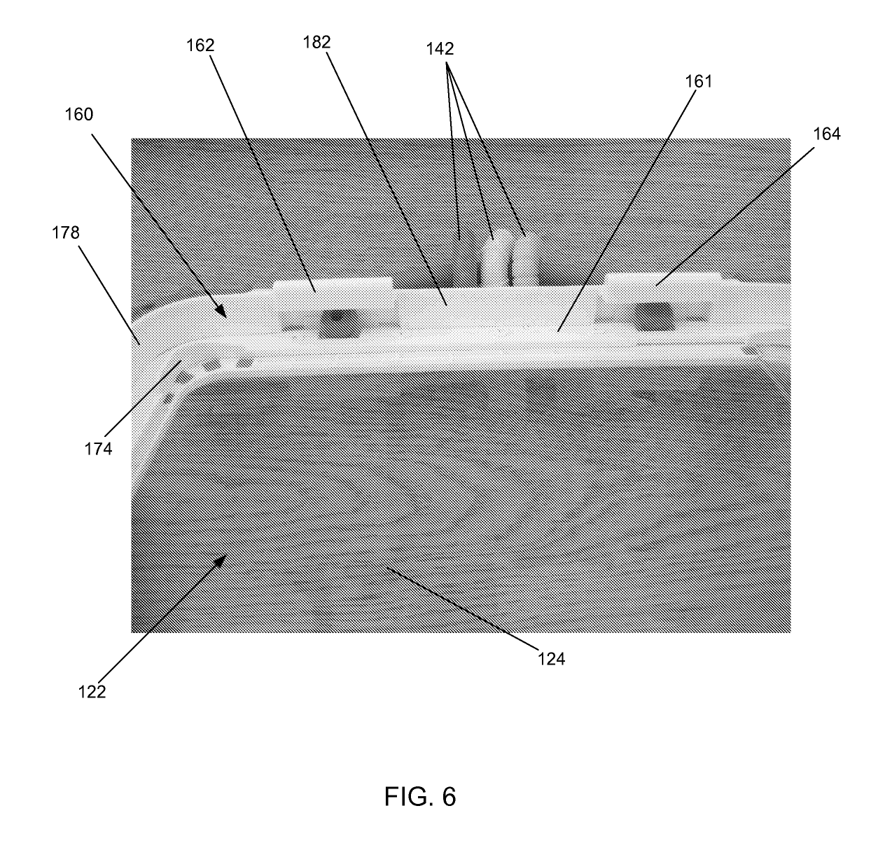

Referring to FIGS. 5 and 6, the cavity 160 contains sidewalls 178, 180 and end walls 182, 184. FIG. 5 illustrates a perspective view of second corner retention member 172. As illustrated, corner member 172 is positioned with the cavity 160 away from sidewall 180 and end wall 184 and proximate to aperture 122. FIG. 6 illustrates a perspective view of the upper portion of the cavity 160 of cover 100. FIG. 6 illustrates that corner member 174 is positioned away from sidewall 178 and end wall 182, proximate to the upper left corner of aperture 122.

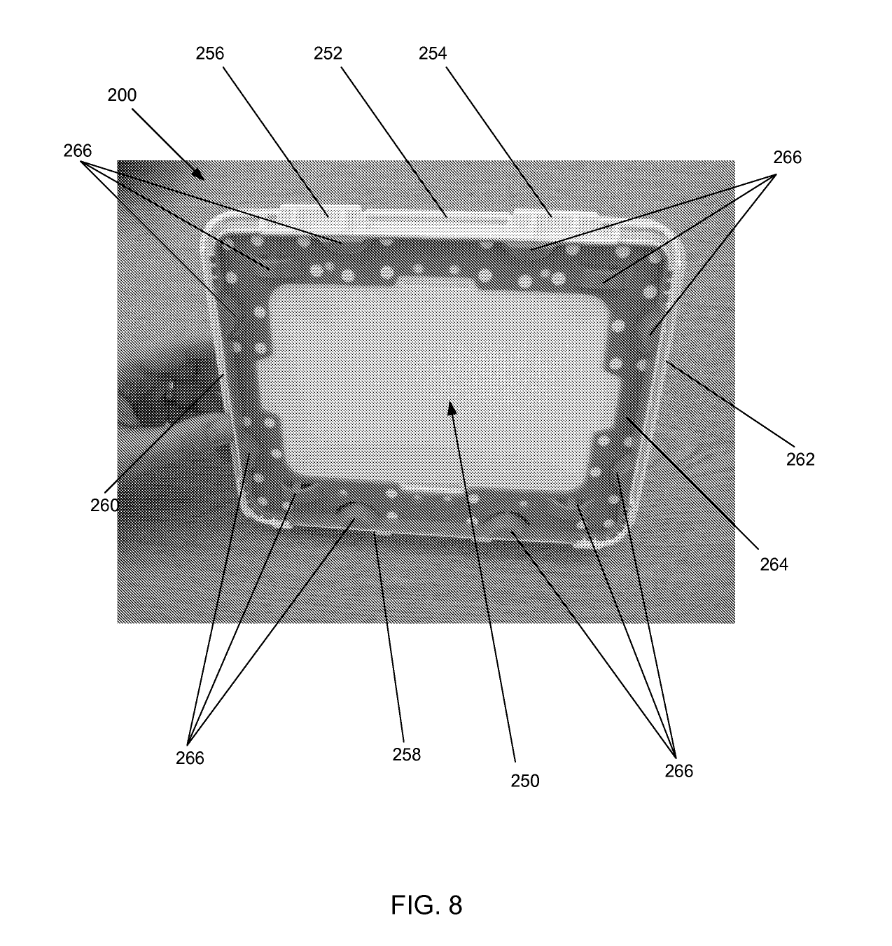

With continued reference to FIG. 6, end wall 182 contains first top flange receiver 162 and second top flange receiver 164. First top flange receiver 162 is configured to receive first fixed flange 254 of the back plate 200, which is illustrated in FIG. 8. Second top flange receiver 164 is configured to receive second fixed flange 256 of the back plate 200, which illustrated in FIG. 8. The flange receivers 162, 164 are positioned to receive the fixed flanges 254, 256 from the back plate 200 to retain the top 212 of the back plate 200 within the cavity 160.

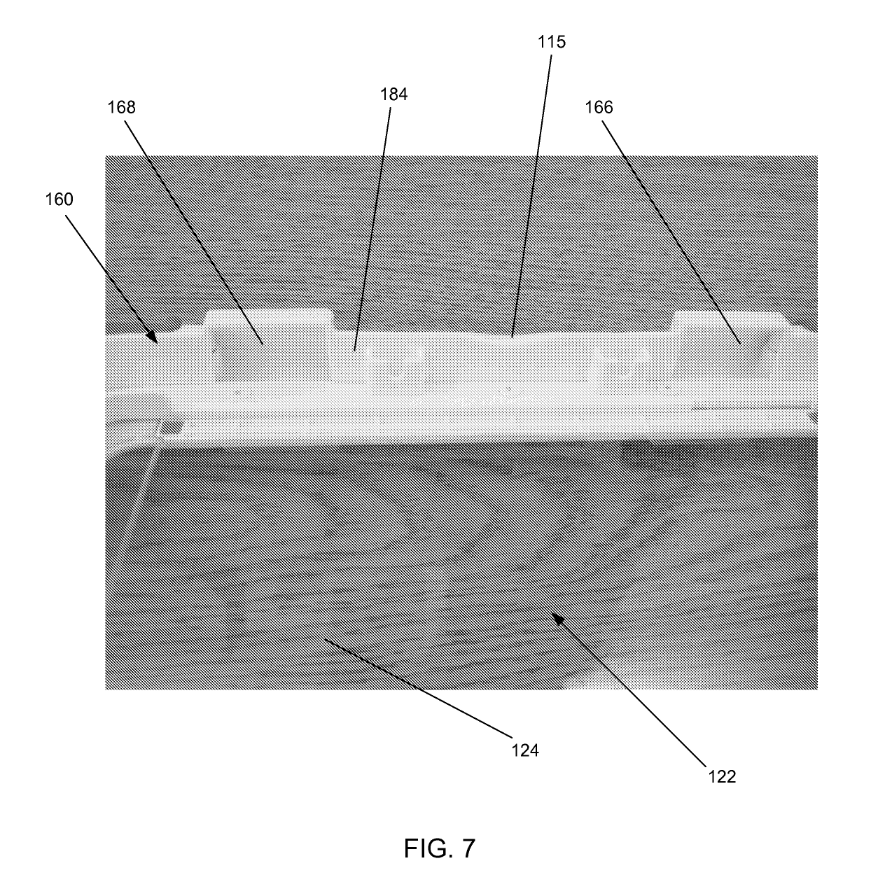

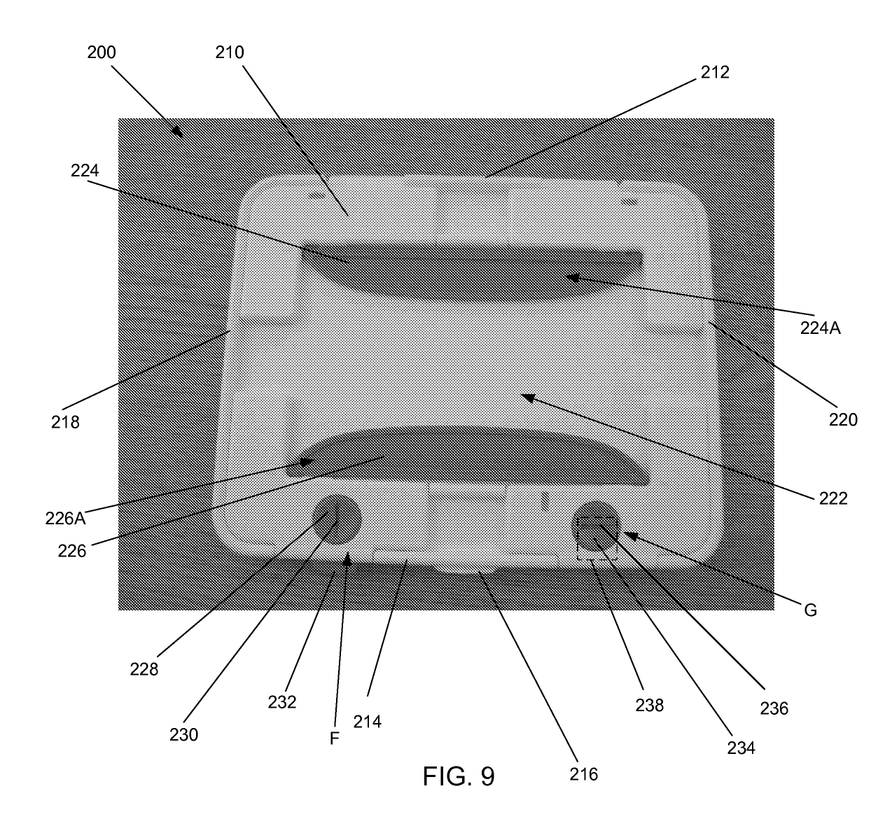

Referring to FIG. 7, illustrated is the bottom portion of the cavity 160 of the cover 100 containing first lock receiver 166 and second lock receiver 168 within end wall 184. First lock receiver 166 receives first lock tab 232 of first lock 228 of back plate 200, which is illustrated in FIG. 9. Second lock receiver 168 receives second lock tab 238 of second lock 234 of back plate 200, which is illustrated in FIG. 9. Lock receivers 166, 168 are configured to receive and hold locking tabs 232, 238 to retain the back plate 200 within cavity 160 and prevent removal movement E, as illustrated in FIG. 3A, of the back plate 200. Furthermore, end wall 184 and bottom 114 contain a depression 115. Depression 115 enables a user's 400 finger to reach underneath tab 216 of back plate 200 to facilitate removal movement E.

Referring to FIG. 8, the interior surface 250 of the back plate 200 is illustrated. Interior surface 250 includes a top portion 252, a bottom portion 258, a left portion 260, and a right portion 262. Interior surface 250 may contain fixed flanges 254 and 256 on top portion 252 that interact with flange receivers 162 and 164 as described previously. Furthermore, interior surface 250 may contain a resilient pad 264 that covers a portion of the interior surface 250. The resilient pad 264 may contain a plurality of resilient members 266. The resilient members 266 serve to cushion and maintain the position of the electronic device 300 within the cavity 160 of the cover 100 when back plate 200 is attached to cover 100. The resilient members 266 are positioned along resilient pad 264 to cushion and maintain the position of the electronic device 300 along both the horizontal axis and vertical axis. The resilient pad 264 and the resilient members 266 may be formed or molded from a thermoplastic elastomer (TPE) material.

Referring to FIG. 9, illustrated is the outer surface 210 of the back plate 200 with locking dials 228 and 234. Locking dials 228, 234 are located along the bottom 214 of the outer surface 210 of the back plate 200. The first locking dial 228 contains a first slot 230 and a first locking tab 232. The second locking dial 234 contains a second slot 236 and a second locking tab 238. Locking tabs 232, 238 are designed to interact with lock receivers 166, 168 as described previously. When locking tabs 232, 238 interact with lock receivers 166, 168, the back plate 200 is locked into cavity 160 of cover 100 housing the electronic device 300 with cavity 160 between cover 100 and back plate 200.

The locking dials 228, 234 rotate between a locked position F and an unlocked position G. When locking dials 228, 234 are positioned in locked position F, locking slots 230, 236 are positioned in a vertical orientation, as illustrated in FIG. 9 by first locking slot 230. Furthermore, when locking dials 228, 234 are positioned in locked position F, locking tabs 232, 238, protrude out of the bottom 214 of back plate 200, enabling the locking tabs 232, 238 to interact with and be received by lock receivers 166, 168. Moreover, when locking dials 228, 234 are positioned in the unlocked position G, locking slots 230, 236 are positioned in a horizontal orientation, as illustrated in FIG. 9 by second locking slot 236. Additionally, when locking dials 228, 234 are positioned in the unlocked position G, locking tabs 232, 238 are stowed within the bottom 214 of back plate 200, preventing the locking tabs 232, 238 from interacting with lock receivers 166, 168. As illustrated, first locking dial 228 is in the locked position F, while second locking dial 234 is in the unlocked position G. In one embodiment, first locking dial 228 may rotate clockwise from locked position F to unlocked position G, while second locking dial 234 may rotate counter-clockwise from locked position F to unlocked position G.

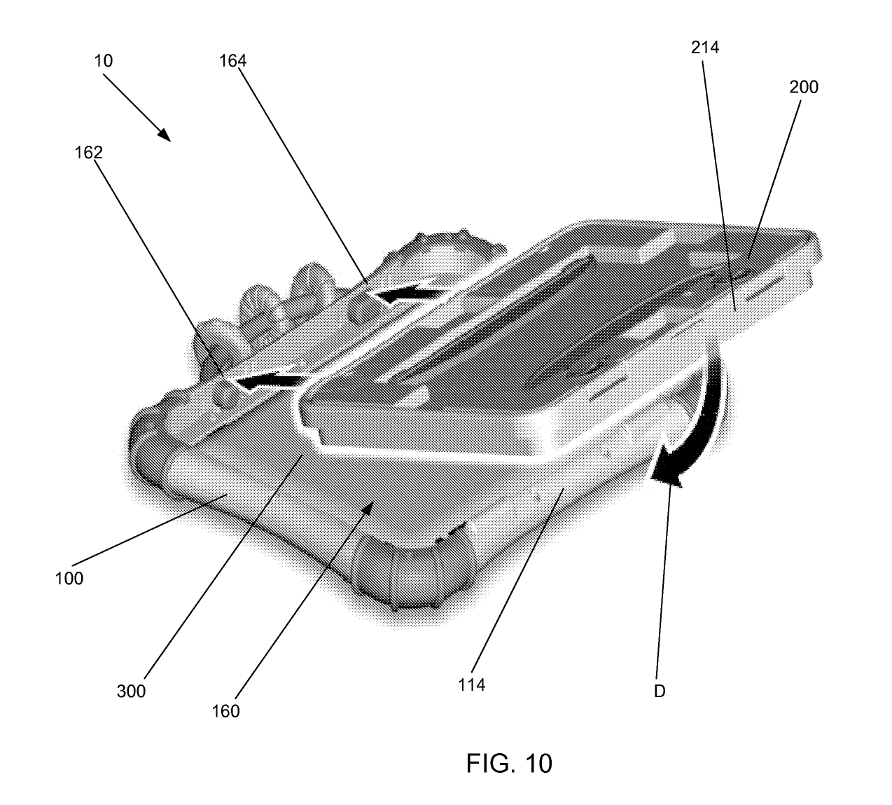

Referring to FIG. 10, illustrated is one embodiment of the interaction between back plate 200 and cover 100. As illustrated in FIG. 10, and as previously discussed, the first fixed flange 254 and the second fixed flange 256 slide into the first flange receiver 162 and the second flange receiver 164, respectively, while the bottom 214 of back plate 200 rotates down into the cavity 160 of cover 100 as indicated by arrow D. Furthermore, as illustrated in FIG. 10, electronic device 300 rests within cavity 160, between cover 100 and back plate 200.

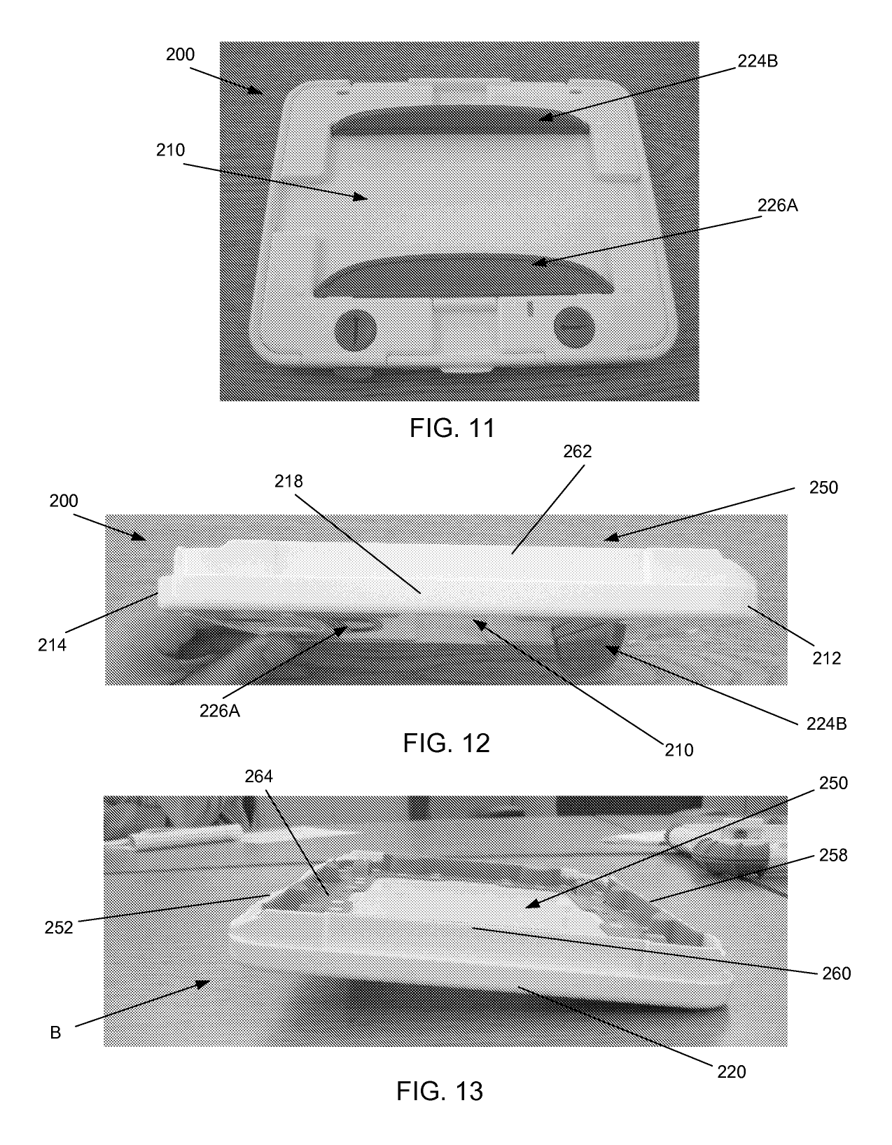

Referring to FIGS. 11 and 12, illustrated is orientation B of the positioning of the supports 224, 226 on the back plate 200 of case 10. In orientation B, first support 224 is positioned in a deployed position 224B, where the first support 224 is extending perpendicular from back plate 200. Furthermore, as illustrated by FIGS. 11 and 12, second support 226 is in the stowed position 226A, where the second support 226 is resting flat against the back plate 200, within recess 210.

With the supports 224, 226 in orientation B, back plate 200 rests at an angle when placed on a support surface, as illustrated in FIG. 13. Because second support 226 is in stowed position 226A and first support 224 is in deployed position 224B, the bottom 214 of back plate 200 rests on the support surface while the top 212 of the back plate 200 is lifted off of the support surface, creating the angled or inclined orientation of the back plate 200 with respect to the support surface.

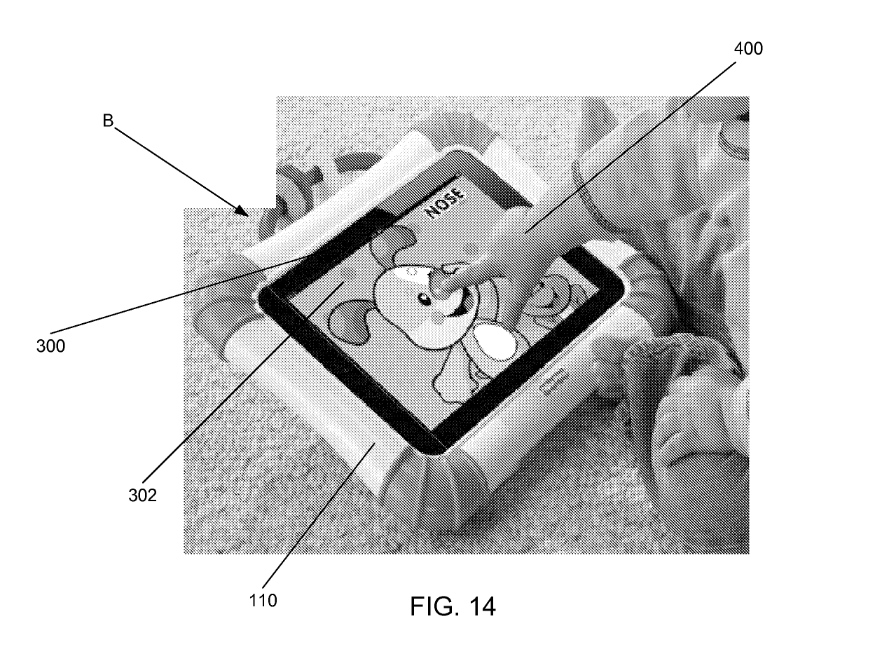

Referring to FIG. 14, illustrated is the case 10 housing electronic device 300 being used by a user 400 with the case 10 in orientation B. The case 10 is set upon a support surface with supports 224, 226 positioned in orientation B as described above. As illustrated by the picture, the top 112 of the cover 100 is lifted above the support surface because first support 224 is in deployed position 224B as described above. The bottom 114 of the cover 100 is in contact with the support surface because the second support 226 is in stowed position 226A as described above. This inclined orientation enables makes it easier for the user 400 to interact with the electronic device 300 without straining the user's 400 back and neck from being bent or hunched over.

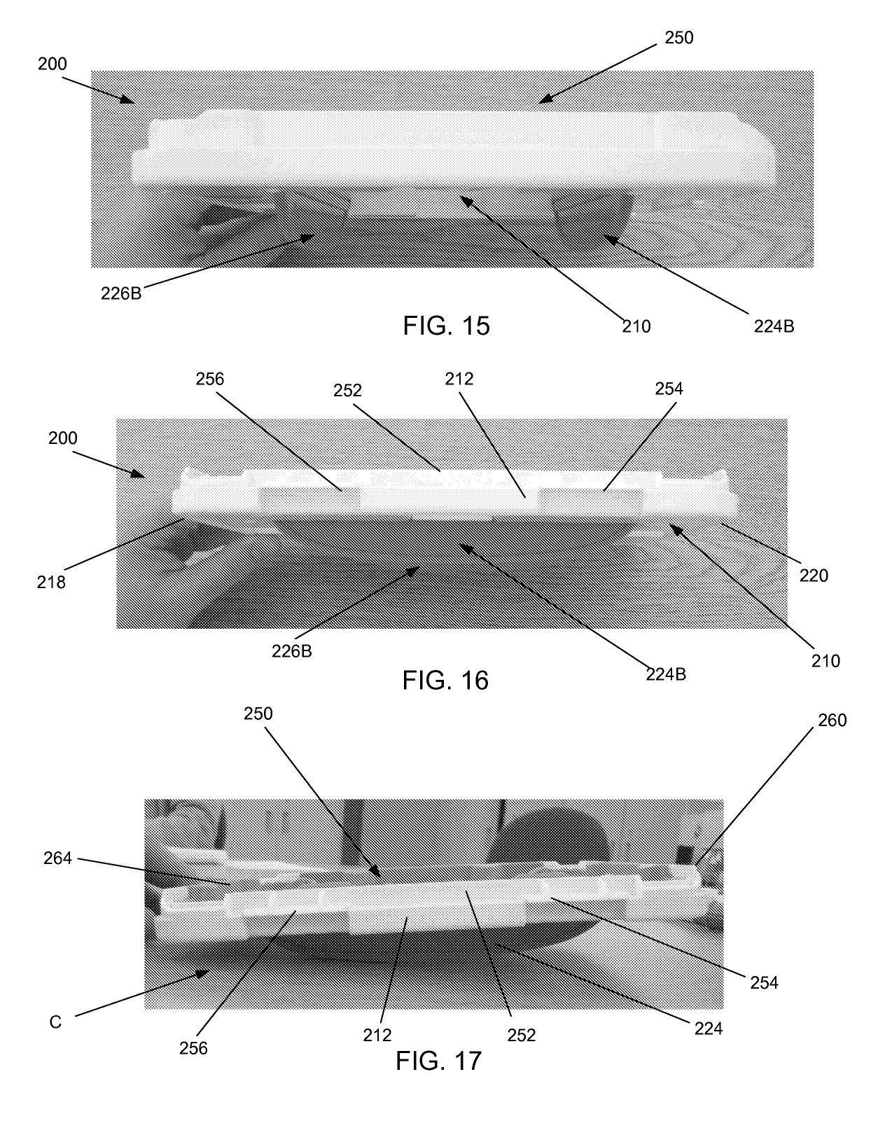

Referring to FIGS. 15 and 16, illustrated is orientation C of the positioning of the supports 224, 226 on the back plate 200 of case 10. In orientation C, first support 224 is positioned in a deployed position 224B, where the first support 224 is extending perpendicular from back plate 200. Furthermore, as illustrated by FIGS. 15 and 16, second support 226 is in the deployed position 226B, where the second support 226 is extending perpendicular from back plate 200.

With the supports 224, 226 in orientation C, back plate 200 is supported on a support surface solely by first support 224 and second support 226, as illustrated in FIG. 17. Because both supports 224, 226 are in deployed positions 224B, 226B the bottom 214 of back plate 200 and the top 212 of the back plate 200 are lifted off of the support surface. In one embodiment, the supports 224, 226 may be rounded, enabling the case 10 to rock side-to-side when the supports are in orientation C.

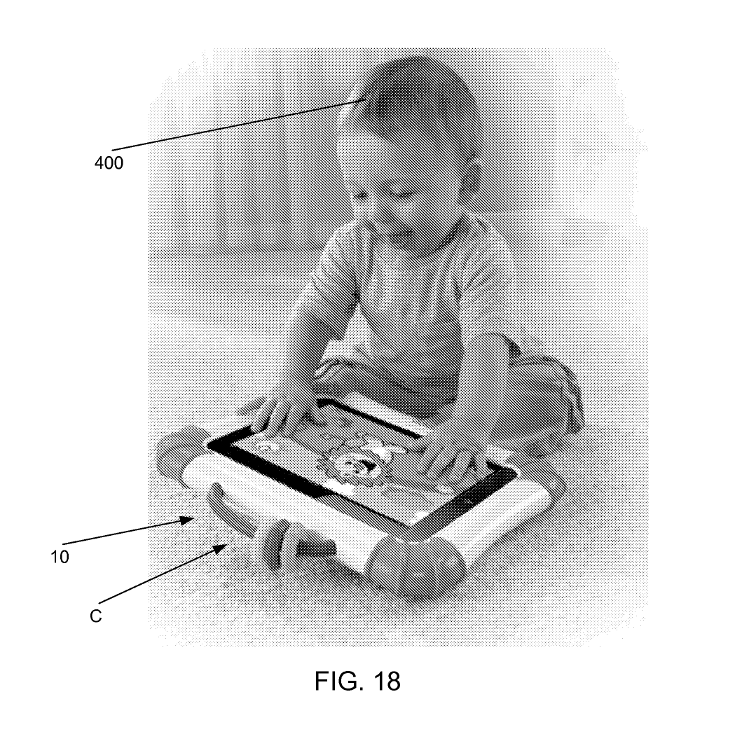

Referring to FIG. 18, illustrated is the case 10 housing electronic device 300 being used by a user 400 with the case 10 in orientation C. The case 10 is set upon a support surface with supports 224, 226 positioned in orientation C as described above. As illustrated by the picture, the top 112 and bottom 114 of the cover 100 are elevated above the support surface because supports 224, 226 are extending perpendicular from the back plate 200 of the case 10. Orientation C enables the user 400 to interact with the electronic device 300 (and its on-board motion detectors) by rocking the case 10 from side-to-side. In one embodiment, where the case 10 contains handle 140 with beads or rings 142, and the case is in orientation C, when the user 400 rocks the case 10 from side-to-side, the beads or rings 142 may slide back and forth along handle 140 between first end 144 and second end 146.

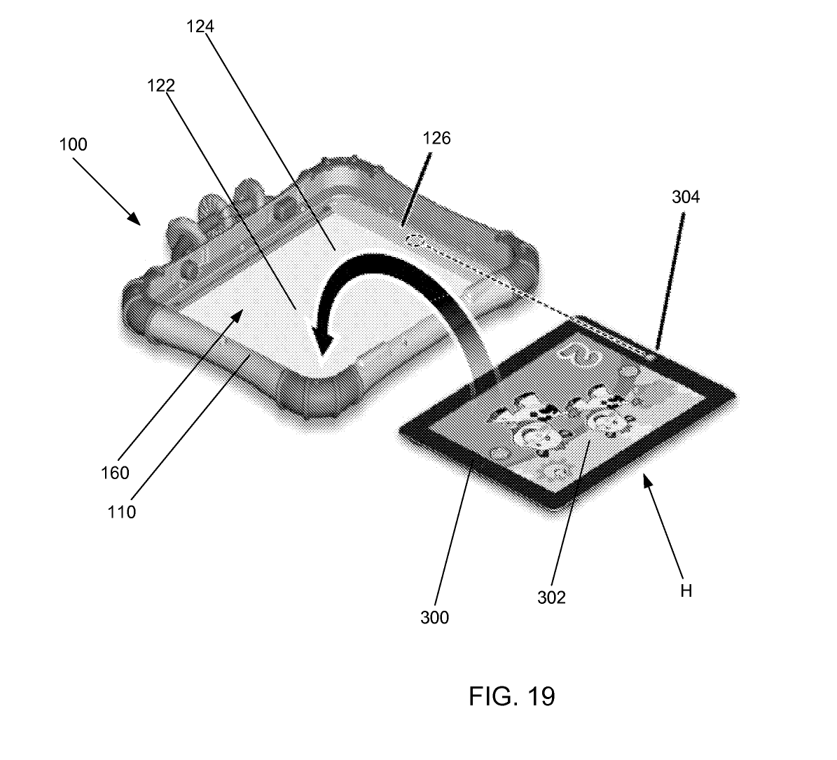

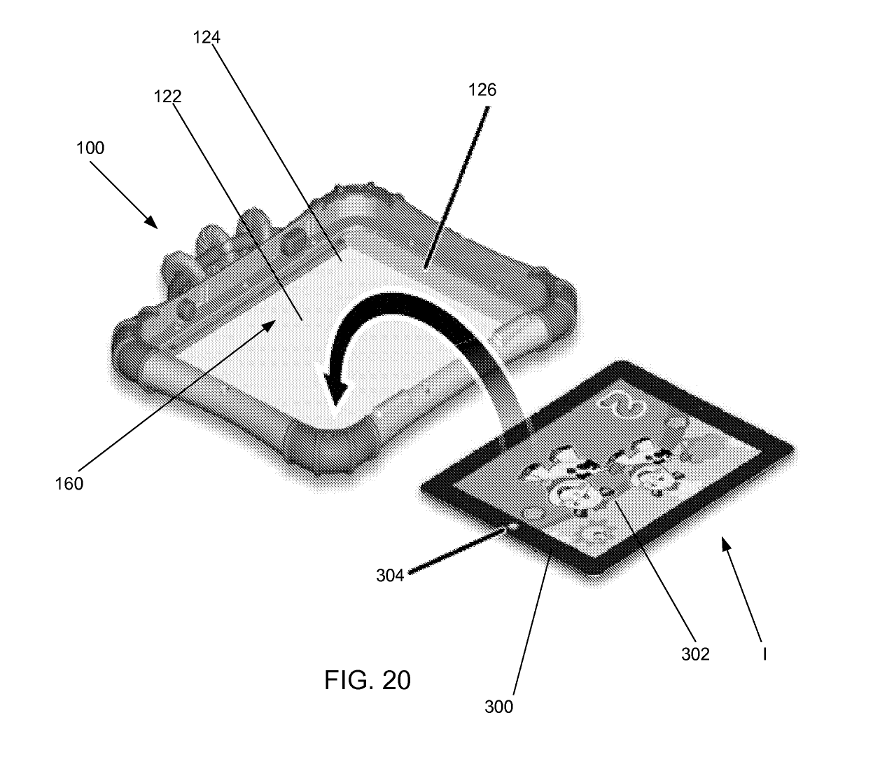

Referring to FIGS. 19 and 20, cover 100 includes an aperture 122 with a protective sheet 124 through which at least a portion of the cover and screen 302, which may be touch-sensitive, of the electronic device 300 are visible when disposed with the cavity 160. The electronic device 300 may include a button 304 (such as a “home button”), which is actuable through the protective sheet 124. The cover 100 and aperture 122 also include a thickened portion or plate 126 adjacent the protective sheet 122 and proximate to a side portion 116, 120 of the cover 100. The plate 126 covers or blocks a portion of the screen 302 and/or front face of the electronic device 300, including the button 304. The button 304 of the electronic device 300 that is covered by the plate 126 is not actuable through the plate 126.

Continuing with FIGS. 19 and 20, the electronic device 300 may be disposed within the cavity 160 of the cover 100 in an orientation H with the button 304 blocked by the plate 126 and not actuable. The electronic device 300 may alternatively be disposed with the cavity 160 in another orientation I with the button 304 accessible through the protective sheet 122. Thus access to the button 304 may be selectively permitted by disposing the electronic device 300 in orientation I, or restricted by disposing the electronic device 300 in orientation H within the cavity 160 of the cover 100.

The disclosed protective case 10 of the present invention permits the user 400 (e.g., a parent or care giver) to selectively block a portion of the screen 302 and/or front face of the electronic device 300 with the plate 126 by selecting the orientation in which the electronic device 300 is disposed within the case 10.

Although the plate 126 is illustrated as being disposed proximate an end of the protective sheet 124, it should be understood that such a plate 126 may be disposed in alternative locations relative to the protective sheet 124. For example, the plate 126 may be located so that other or additional areas of the screen 302 and/or front face of the electronic device 300 are not actuable.

Moreover, the plate 126 may be movable to a selected area of the aperture 122 of the cover 100, so that a selected portion of the protective sheet 124 may be covered and rendered not actuable. For example, the aperture 122 may include defined receiving areas or zones in which the plate 126 is selectively receivable.

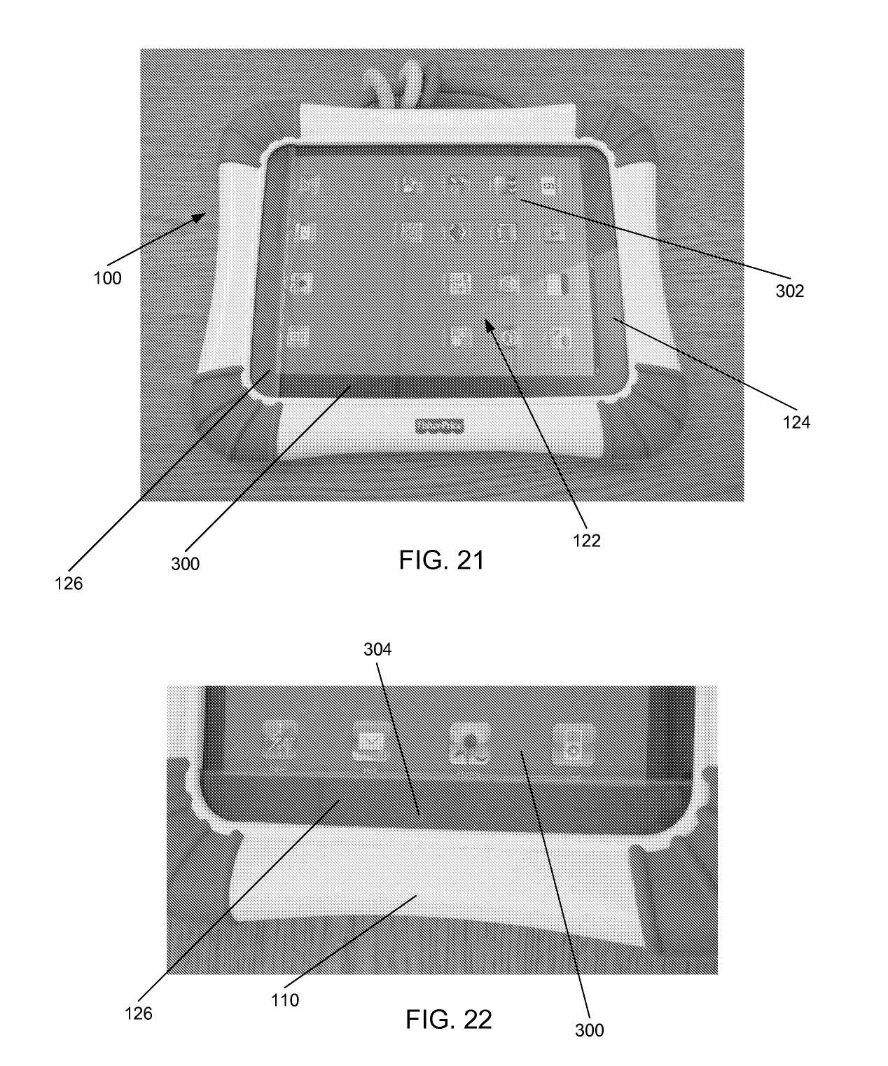

Referring to FIGS. 21 and 22, illustrated are front perspective views of the case 10 housing electronic device 300 in orientation H. As illustrated in FIG. 21, in this embodiment, the plate 126 is located in aperture 122 proximate to the left portion 116 of the cover 100. As illustrated in FIG. 22, the button 304 of electronic device 300 is positioned behind plate 126. As discussed previously, when the button 304 of electronic device 300 is positioned behind plate 126, the button 304 is not actuable by a user 400.

Although the disclosed inventions are illustrated and described herein as embodied in one or more specific examples, it is nevertheless not intended to be limited to the details shown, since various modifications and structural changes may be made therein without departing from the scope of the inventions and within the scope and range of equivalents of the claims. For example, although the illustrated embodiments are shown with an iPad® device, the case of the present invention could be used with any portable electronic device, including, but not limited to cellular phones, smart phones, media players, PDAs, and portable or tablet computers. In addition, various features from one of the embodiments may be incorporated into another of the embodiments. Accordingly, it is appropriate that the claims be construed broadly and in a manner consistent with the scope of the disclosure as set forth in the following claims.

What is claimed is:

1. A protective case for a portable electronic device, comprising:
a housing configured to surround a portion of an electronic device, the housing including an aperture for viewing a screen on the electronic device;
a first support movably coupled to the housing, the first support having a curved surface engageable with a support surface; and
a second support movably coupled to the housing, the second support having a curved surface engageable with a support surface, each of the supports being pivotable between a deployed position that allows the housing to rock side-to-side, and a retracted position relative to the housing.

2. The protective case of claim 1, wherein the housing includes a front cover and a removable back plate.

3. The protective case of claim 2, wherein the aperture is disposed on the front cover.

4. The protective case of claim 2, wherein the first and second supports are pivotably coupled to the removable back plate.

5. The protective case of claim 1, wherein the supports pivot independent of each other relative to the housing.

6. The protective case of claim 1, wherein the housing includes at least one guard disposed on the housing, the guard being configured to protect a screen of the electronic device.

7. The protective case of claim 6, wherein the guard is configured to at least partially cover the aperture.

8. The protective case of claim 6, wherein the guard includes at least one plate disposed on the guard, the plate being configured to prevent the activation of at least one button of the electronic device.

9. The protective case of claim 1, further comprising:
an arch with a first end and a second end opposite the first end, the arch being coupled to the cover at the first end and the second end; and
at least one activity bead slidably disposed on the arch, wherein the at least one activity bead slides back and forth along the arch when the cover rocks side-to-side on the rounded supports.

10. A protective case for an electronic portable device, comprising:
a cover configured to surround a portion of an electronic device, the cover including an aperture for viewing the electronic device;
a removable back plate coupleable to the cover; and
a first rounded support and second rounded support, each of the rounded supports being coupled to the back plate and pivotable between a deployed position that allows the cover to rock side-to-side, and stowed position in which the rounded support is proximate to the back plate.

11. The protective case of claim 10, wherein the back plate includes at least one lock for locking the back plate onto the cover.

12. The protective case of claim 10, wherein the back plate includes at least one tab for facilitating removal of the back plate from the cover.

13. The protective case of claim 10, wherein the cover includes at least one guard disposed on the cover, the guard being configured to protect a screen of the electronic device.

14. The protective case of claim 13, wherein the guard includes at least one plate disposed on the guard, the plate being configured to prevent the activation of at least one button of the electronic device.

15. The protective case of claim 10, wherein the rounded supports pivot independent of each other.

16. The protective case of claim 10, further comprising:
an arch with a first end and a second end opposite the first end, the arch being coupled to the cover at the first end and the second end; and
at least one activity bead slidably disposed on the arch, wherein the at least one activity bead slides back and forth along the arch when the cover rocks side-to-side on the rounded supports.

17. A protective case for an electronic portable device, comprising:
a cover configured to house an electronic device, the cover including a front with an aperture, and a back with an opening; and
a back plate dimensioned to removably fit within the opening on the back of the cover;
a protective sheet configured to prevent debris and liquids from contacting an electronic device, the protective sheet being located in the aperture on the front of the cover; and
at least two rounded supports pivotally mounted on the back plate, wherein each of the rounded supports pivots between a deployed position where the rounded support is positioned perpendicular to the back plate, and a stowed position where the rounded support lays flat proximate to the back plate.

18. The protective case of claim 17, wherein the protective sheet includes at least one plate disposed on the protective sheet, the plate being configured to prevent the activation of at least one button of the electronic device.

19. The protective case of claim 17, wherein the cover includes at least one retention member configured to position the electronic device to be viewed through the aperture.

20. The protective case of claim 17, wherein the back plate includes at least one resilient member to retain the electronic device in position between the cover and the back plate to be viewed through the aperture.
